(19) United States
(12) Patent Application Publication
(10) Pub. No.: US 2026/0233946 A1
(43) Pub. Date: Aug. 13, 2026

(54) COMPLIANT END-EFFECTOR FOR LOW-PARTICLE ATMOSPHERIC HANDLING OF WARPED WAFERS

(71) Applicant: Applied Materials, Inc., Santa Clara, CA (US)

(72) Inventors: Michael W. Osborne, Clinton, MA (US); Fletcher Ian Potter, IV, Beverly, MA (US); Brant Steven Binns, Beverly, MA (US)

(73) Assignee: Applied Materials, Inc., Santa Clara, CA (US)

(21) Appl. No.: 19/050,747

(22) Filed: Feb. 11, 2025

(51) Int. Cl. B65G 47/90; H01L 21/683; H01L 21/687

(52) U.S. Cl. CPC B65G 47/90; H10P 72/7602; H10P 72/78

(57) ABSTRACT

Devices, systems, and methods for handling a wafer can include the use of an end effector comprising a pick body and one or more vacuum pick pad assembly attached to the pick body. Each vacuum pick pad assembly can include a pad base fixedly coupled to the pick body and a gimballed pad arranged against the pad base, where the gimballed pad is slidably movable relative to the pad base to any of a range of angular positions relative to the pad base. In addition, a suction path is arranged within the pick body in communication between a suction source and the gimballed pad.

### TECHNICAL FIELD

Embodiments of the present disclosure relate generally to wafer handling and, more specifically, to an equipment front end module vacuum pick pad for wafer handling.

### BACKGROUND

An equipment front end module (EFEM) pick relies on a robust vacuum seal between the wafer and EFEM vacuum pick pad to effectively secure the wafer during transfer to and from a front-opening unified pod (FOUP), a front-opening shipping box (FOSB), a cassette, or any of a variety of other transport configurations. Current EFEM picks use a single large and centrally located vacuum pick pad to secure the wafer. Bowed or warped wafers present a particular challenge to safe wafer handing since the pad cannot readily conform to wafer irregularities to effectuate a good vacuum seal. This condition can cause vacuum leaks between the wafer and pick pads, which can result in insufficient wafer clamping force and the possibility of the wafer shifting on or falling off the pick during transfer. Either event can result in a wafer loss.

Although system software can be configured to monitor the quality of the vacuum between the pads and wafer, the operation of such monitoring can only produce an alarm that alerts the operator. Thus, if a vacuum leak is detected by such a system, the wafer transfer is prevented, requiring operator intervention and negatively impacting wafer throughput.

It is with respect to these and other deficiencies of current approaches that the present disclosure is provided.

### SUMMARY

In accordance with this disclosure, devices, systems, and methods for handling a wafer are provided. In one aspect, a wafer handling system can include an end effector comprising a pick body and one or more vacuum pick pad assembly attached to the pick body. Each vacuum pick pad assembly can include a pad base fixedly coupled to the pick body and a gimballed pad arranged against the pad base. In some embodiments, the gimballed pad is slidably movable relative to the pad base to any of a range of angular positions relative to the pad base. In some embodiments, a suction path is arranged within the pick body in communication between a suction source and the gimballed pad.

In another aspect, a vacuum pick pad assembly for use in a wafer handling system can include a pad base configured to be fixedly coupled to a body of an end effector of the wafer handling system. A gimballed pad can be arranged against the pad base, the gimballed pad defining a wafer contact portion that is configured to conformally seal against a wafer surface. In this configuration, the gimballed pad can be slidably movable relative to the pad base to any of a range of angular positions relative to the pad base.

In another aspect, a method for handling a wafer can include positioning an end effector proximate to a wafer, the end effector comprising a pick body, positioning one or more vacuum pick pad assembly attached to the pick body against a surface of the wafer, and creating suction at each vacuum pick pad assembly to secure the vacuum pick pad assembly against the surface of the wafer. In some embodiments, each of the one or more vacuum pick pad assembly can include a pad base fixedly coupled to the pick body and a gimballed pad arranged against the pad base, where positioning the one or more vacuum pick pad assembly against the surface of the wafer involves slidably moving the gimballed pad relative to the pad base to any of a range of angular positions relative to the pad base to align the gimballed pad with the surface of the wafer.

In any preceding or subsequent example, the one or more vacuum pick pad assembly can include a plurality of vacuum pick pad assemblies spaced apart about a surface of the pick body.

In any preceding or subsequent example, each vacuum pick pad assembly is positioned within a cavity arranged within the pick body, the cavity including an opening through which a portion of the gimballed pad is configured to protrude. In some such examples, a cover is positioned to secure the pad base in place within the cavity. In some examples, each cavity is substantially sealed such that connection to the suction path creates a vacuum environment within the cavity.

In any preceding or subsequent example, the pad base of each vacuum pick pad assembly includes a curved contact surface, and a corresponding gimballed pad includes a curved interface configured to be positioned against the curved contact surface. In this arrangement, movement of the gimballed pad with respect to the pad base causes a change in an angle of the gimballed pad within the range of angular positions relative to the pad base.

In any preceding or subsequent example, the gimballed pad of each vacuum pick pad assembly defines a wafer contact portion that is configured to conformally seal against a wafer surface.

In any preceding or subsequent example, one or more mapping sensor component can be coupled to an end of the end effector to detect the presence of a wafer near the end of the end effector.

Although some of the aspects of the subject matter disclosed herein have been stated hereinabove, and which are achieved in whole or in part by the presently disclosed subject matter, other aspects will become evident as the description proceeds when taken in connection with the accompanying drawings as best described hereinbelow.

### BRIEF DESCRIPTION OF THE DRAWINGS

The features and advantages of the present subject matter will be more readily understood from the following detailed description which should be read in conjunction with the accompanying drawings that are given merely by way of explanatory and non-limiting example, and in which:

FIG. 1 illustrates a perspective top view of an end effector including a plurality of vacuum pick pad assemblies of a wafer handling system according to an embodiment of the presently disclosed subject matter;

FIGS. 2-4 illustrate cutaway side views of a vacuum pick pad of a wafer handling system according to an embodiment of the presently disclosed subject matter;

FIG. 5 illustrates a top view of a vacuum pick pad of a wafer handling system according to an embodiment of the presently disclosed subject matter; and

FIG. 6 illustrates a process flow for wafer handling according to an embodiment of the presently disclosed subject matter.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

The present embodiments will now be described more fully hereinafter with reference to the accompanying drawings, wherein some embodiments are shown. The subject matter of the present disclosure may be embodied in many different forms and is not to be construed as limited to the embodiments set forth herein. These embodiments are provided so this disclosure will be thorough and complete, and will convey certain exemplary aspects of the subject matter to those skilled in the art. In the drawings, like numbers refer to like elements throughout.

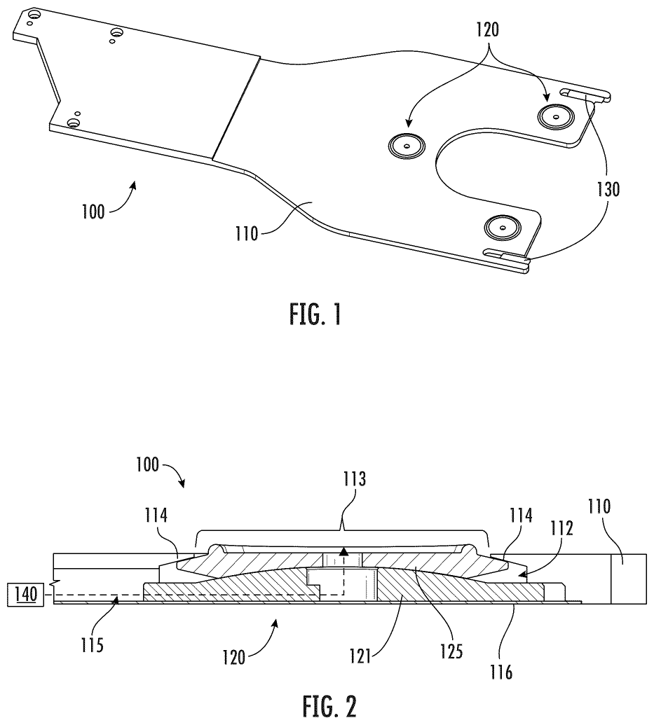

The present subject matter provides systems, devices, and methods for wafer handling using one or more adjustable vacuum pick pads that are movable to conform to a non-planar and/or non-uniform wafer surface. Referring to an example configuration illustrated in FIG. 1, an end effector 100 for a wafer handling system defines a pick body 110, sometimes also referred to as a “blade.” One or more vacuum pick pad assemblies 120 is attached to the pick body 110. In some embodiments, a plurality of vacuum pick pad assemblies 120 are spaced apart about a surface of the pick body 110. For instance, in the example configuration illustrated in FIG. 1, three pads are arranged about the pick body 110, although those having ordinary skill in the art will recognize that more or fewer pick pad assemblies can be used in accordance with the present subject matter. In this configuration, in situations in which a single, large pad would not be able to conform to irregularities in the wafer contour, which could prevent formation of a good vacuum seal, the plurality of vacuum pick pad assemblies 120 can each locally conform to different, dispersed portions of the wafer.

In some embodiments, the end effector 100 can further include one or more optional mapping sensor component 130 coupled to the end effector 100 and configured to detect the presence of a wafer near the end of the end effector 100. In some examples, the one or more mapping sensor component 130 is an optical sensor that extends from an end of the end effector 100 and is configured to detect wafers even just a few μm thick with extreme precision. This configuration can allow the one or more mapping sensor component 130 to detect potential loading errors and prevent the risk of breakage. Although a mapping blade configuration is shown in FIG. 1, those having ordinary skill in the art will recognize that the principles discussed herein can likewise be applied to a non-mapping blade.

Regardless of the particular configuration of the pick body 110, in contrast to conventional vacuum pick pads that are substantially fixed in position relative to a pick body, the orientation of contact surfaces of the one or more vacuum pick pad assembly 120 according to the present subject matter can be individually adjustable relative to the pick body 110 to conform to a non-planar and/or otherwise non-uniform wafer surface.

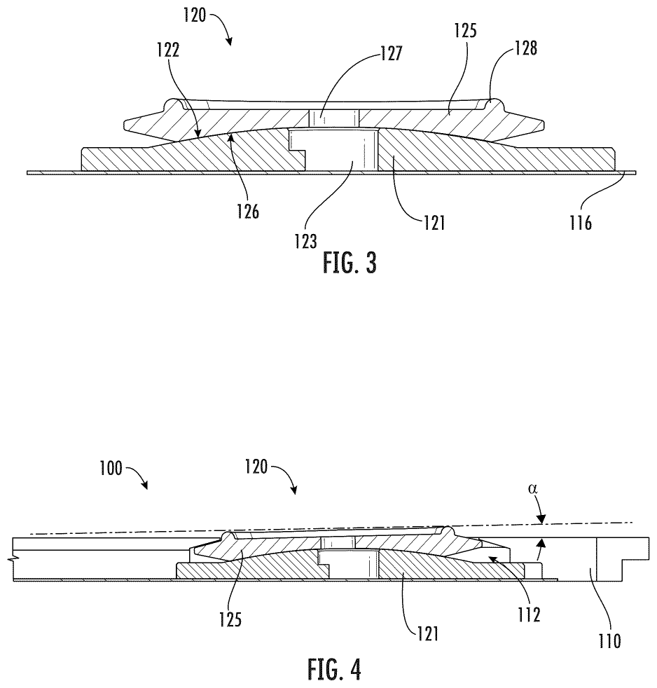

Referring to FIGS. 2-4, in some embodiments, each vacuum pick pad assembly 120 can include a pad base 121 that is fixedly coupled to the pick body 110 and a gimballed pad 125 arranged against the pad base 121. In this configuration, the gimballed pad 125 can be slidably movable relative to the pad base 121 to any angle a within a range of angular positions relative to the pad base 121 (and correspondingly relative to the pick body 110). In some examples, the gimballed pad 125 is movable relative to the pad base 121 to any of a range of offset positions through and arc of approximately ±1.5° to 2°. To achieve this adjustability, in some embodiments, the pad base 121 can include a curved contact surface 122, and the gimballed pad 125 can include a correspondingly curved interface 126 that is configured to be positioned against the contact surface 122. In the configuration illustrated in FIGS. 2-4, for example, the curved contact surface 122 is convex, and the curved interface 126 is concave. In some embodiments, the shapes of both of the curved contact surface 122 and the curved interface 126 have substantially spherical shapes. In this configuration, if the gimballed pad 125 is moved laterally relative to the pad base 121 while maintaining contact between the contact surface 122 and the interface 126, such movement results in a change in the angle a of the gimballed pad 125 relative to the pad base 121, such as is shown in FIG. 4. In some embodiments, the contact surface 122 and interface 126 are formed in a manner that eliminates the need for a separate seal to maintain vacuum integrity.

In some embodiments, each vacuum pick pad assembly 120 is integrated into the structure of the end effector 100. Referring to FIGS. 2 and 4, the pick body 110 can include one or more cavity 112 that is sized and configured to receive therein a corresponding vacuum pick pad assembly 120. In some embodiments, each cavity 112 is sized and configured to receive the pad base 121 in a substantially fixed position relative to the pick body 110, and the gimballed pad 125 can be arranged against the pad base 121 but movable to a range of positions within the cavity 112. Each cavity 112 can further include an opening 113 out of the pick body 110 through which a portion of the gimballed pad 125 is configured to protrude. In some embodiments, the opening 113 is delimited by a flange or lip 114 that surrounds the opening 113 and retains the gimballed pad 125 within the cavity 112.

In some embodiments, the end effector 100 further includes a cover 116 that is configured to be secured against the pick body 110 to retain the pad base 121 in place within the cavity 112. In some examples, the cover 116 is secured to the pick body 110 by an adhesive, by one or more screws or other fasteners, or by any other attachment mechanism known to those having ordinary skill in the art. Alternatively, in some embodiments, the pad base 121 is integrally formed with the cover 116.

To enable operation as a vacuum pick pad, in some embodiments, a suction path 115 is arranged within the pick body 110 in communication between a suction source 140 and each of the gimballed pads 125. In some embodiments, for example, the pad base 121 includes an internal conduit 123 configured to be arranged in communication with the suction path 115, and the gimballed pad 125 includes a suction orifice 127 that is configured to be aligned with the internal conduit 123. The interfaces between each of the pick body 110, the pad base 121, and the gimballed pad 125 can be configured to be substantially sealed to maintain suction along the suction path 115. Alternatively, or in addition, in some examples, each cavity 112 is substantially sealed such that connection to the suction path 115 creates a vacuum environment within each cavity 112 in which each vacuum pick pad assembly 120 is arranged. In examples in which the vacuum pick pad assembly 120 is secured within the cavity 112 by a cover 116, the cover 116 can act both to physically retain the vacuum pick pad assembly 120 in the cavity 112 and to maintain the vacuum environment within the cavity 112. In any configuration, the configuration of the vacuum pick pad assembly 120, the cavity 112, and/or the pick body 110 can be designed such that no additional seal (e.g., an elastomeric gasket or the like) is required to maintain the desired suction at the interface between the gimballed pad 125 and the wafer.

In some embodiments, the gimballed pad 125 further includes a wafer contact portion 128 that is configured to conformally seal against a wafer surface. In some examples, such a conformal seal can reduce the introduction of backside particles at the interface between the gimballed pad 125 and the wafer. In some particular embodiments, the wafer contact portion 128 includes a substantially ring-shaped protrusion that extends from the portion of the gimballed pad 125 that protrudes out of the cavity 112 through the opening 113 in the pick body 110. In some examples, the wafer contact portion 128 and/or the entire gimballed pad 125 are formed from a material that exhibits sufficient elasticity to substantially conform to a wafer surface. In addition, in some embodiments, the geometry of the wafer contact portion 128 and/or the entire gimballed pad 125 and/or the material of the component is selected to minimize particle generation due to contact between the gimballed pad 125 and the wafer. Those having ordinary skill in the art will recognize that such material selections can be dependent on the material of the wafer to be engaged.

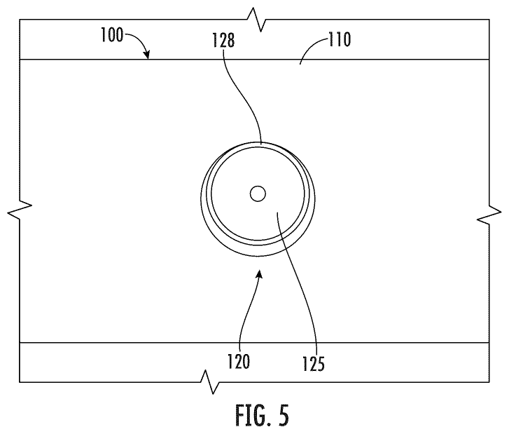

In some examples, the wafer contact portion 128 can further serve as a stop that is configured to abut the edge of the opening 113 in the pick body 110 (e.g., at the lip 114) to thereby prevent movement of the gimballed pad 125 relative to the pad base 121 beyond the desired range of lateral/angular movement. As illustrated in FIGS. 4 and 5, for example, a difference between a size of the opening 113 and a size and configuration of the wafer contact portion 128 can be designed to allow only the desired range of movement of the gimballed pad 125. In this way, the relative sizes and configurations of the opening 113 and the wafer contact portion 128 can be designed such that a position at which the wafer contact portion 128 abuts the edge of the opening 113 to prevent further movement of the gimballed pad 125 corresponds to a position in which the gimballed pad 125 is moved relative to the pad base 121 to a maximum desired angle a.

In any configuration, the configuration of the one or more vacuum pick pad assembly 120 permits a freedom of movement of the gimballed pad 125 to conform to a bowed or warped wafer, allowing full contact between each gimballed pad 125 and wafer and effectuating a complete vacuum seal.

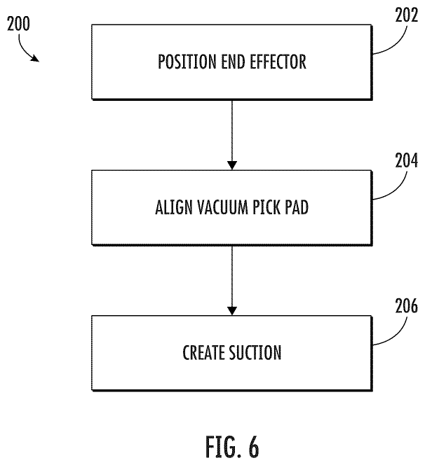

Thus, in another aspect, methods for wafer handling using one or more adjustable vacuum pick pads are illustrated in FIG. 6. The method for handling a wafer, generally designated 200, can include a positioning process 202 in which the end effector 100 is positioned proximate to a wafer, an alignment process 204 in which one or more vacuum pick pad assembly 120 attached to the pick body 110 against a surface of the wafer, which can include slidably moving the gimballed pad 125 relative to the pad base 121 to any of a range of angular positions relative to the pad base 121 to align the gimballed pad 125 with the surface of the wafer, and a vacuum process 206 in which suction is created at the gimballed pad 125 to secure the gimballed pad 125 against the surface of the wafer.

As indicated above, in some embodiments, the positioning process 202 can include detecting the presence of a wafer near the end of the end effector using one or more mapping sensor component 130 coupled to an end of the end effector 100.

Further, in some embodiments, the alignment process 204 can include positioning a plurality of vacuum pick pad assemblies 120 that are spaced apart about a surface of the pick body 110 against different portions of the surface of the wafer. Each of the vacuum pick pad assemblies 120 can be provided in any of configurations described above. In some embodiments, the alignment process 204 can include slidably moving a curved interface 126 of the gimballed pad 125 relative to a curved contact surface 122 of the pad base 121, which causes a change in an angle of the gimballed pad 125 within the range of angular positions relative to the pad base 121. Further, in some embodiments, the alignment process 204 can include conformally sealing a wafer contact portion 128 of each of the one or more gimballed pad against the wafer surface.

In some embodiments, the vacuum process 206 can include connecting the gimballed pad 125 to a suction source 140 via a suction path 115 arranged within the pick body 110.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, while the present disclosure has been described herein in the context of a particular implementation in a particular environment for a particular purpose, those of ordinary skill in the art will recognize its usefulness is not limited thereto. Embodiments of the present disclosure may be beneficially implemented in any number of environments for any number of purposes. Accordingly, the claims set forth below shall be construed in view of the full breadth and spirit of the present disclosure as described herein.

What is claimed is:

1. A wafer handling system comprising:
an end effector comprising a pick body; and
one or more vacuum pick pad assembly attached to the pick body, each of the one or more vacuum pick pad assembly comprising:
a pad base fixedly coupled to the pick body; and
a gimballed pad arranged against the pad base, wherein the gimballed pad is slidably movable relative to the pad base to any of a range of angular positions relative to the pad base;
wherein a suction path is arranged within the pick body in communication between a suction source and the gimballed pad.

2. The system of claim 1, wherein the one or more vacuum pick pad assembly comprises a plurality of vacuum pick pad assemblies spaced apart about a surface of the pick body.

3. The system of claim 1, wherein each of the one or more vacuum pick pad assembly is positioned within a cavity arranged within the pick body; and
wherein the cavity comprises an opening through which a portion of the gimballed pad is configured to protrude.

4. The system of claim 3, wherein a cover is positioned to secure the pad base in place within the cavity.

5. The system of claim 1, wherein the pad base of each of the one or more vacuum pick pad assembly comprises a curved contact surface; and
wherein a corresponding one of the gimballed pad of each of the one or more vacuum pick pad assembly comprises a curved interface configured to be positioned against the curved contact surface;
wherein movement of the gimballed pad with respect to the pad base causes a change in an angle of the gimballed pad within the range of angular positions relative to the pad base.

6. The system of claim 1, wherein the gimballed pad of each of the one or more vacuum pick pad assembly comprises a wafer contact portion that is configured to conformally seal against a wafer surface.

7. The system of claim 1, comprising one or more mapping sensor component coupled to an end of the end effector and configured to detect the presence of a wafer near the end of the end effector.

8. A vacuum pick pad assembly for use in a wafer handling system, the assembly comprising:
a pad base configured to be fixedly coupled to a body of an end effector of the wafer handling system; and
a gimballed pad arranged against the pad base, the gimballed pad comprising a wafer contact portion that is configured to conformally seal against a wafer surface;
wherein the gimballed pad is slidably movable relative to the pad base to any of a range of angular positions relative to the pad base.

9. The assembly of claim 8, wherein the pad base comprises a curved contact surface;
wherein the gimballed pad comprises a curved interface configured to be positioned against the curved contact surface; and
wherein movement of the gimballed pad with respect to the pad base causes a change in an angle of the gimballed pad within the range of angular positions relative to the pad base.

10. The assembly of claim 9, wherein the curved contact surface comprises a substantially spherical contact surface; and
wherein the curved interface comprises a substantially spherical interface.

11. The assembly of claim 8, wherein the gimballed pad comprises a wafer contact portion that is configured to conformally seal against a wafer surface.

12. The assembly of claim 11, wherein the wafer contact portion is substantially ring-shaped.

13. A method for handling a wafer, the method comprising:
positioning an end effector proximate to a wafer, the end effector comprising a pick body;
positioning one or more vacuum pick pad assembly attached to the pick body against a surface of the wafer, each of the one or more vacuum pick pad assembly comprising:
a pad base fixedly coupled to the pick body; and
a gimballed pad arranged against the pad base;
wherein positioning the one or more vacuum pick pad assembly against the surface of the wafer comprises slidably moving the gimballed pad relative to the pad base to any of a range of angular positions relative to the pad base to align the gimballed pad with the surface of the wafer; and
creating suction at the gimballed pad to secure the gimballed pad against the surface of the wafer.

14. The method of claim 13, wherein positioning the one or more vacuum pick pad assembly comprises positioning a plurality of vacuum pick pad assemblies that are spaced apart about a surface of the pick body against different portions of the surface of the wafer.

15. The method of claim 13, wherein each of the one or more vacuum pick pad assembly is positioned within a cavity arranged within the pick body; and
wherein a portion of the gimballed pad protrudes through an opening in the pick body in communication with the cavity.

16. The method of claim 15, comprising positioning a cover to secure the pad base in place within the cavity.

17. The method of claim 13, wherein slidably moving the gimballed pad relative to the pad base comprises slidably moving a curved interface of the gimballed pad relative to a curved contact surface of the pad base;
wherein slidably moving the gimballed pad relative to the pad base causes a change in an angle of the gimballed pad within the range of angular positions relative to the pad base.

18. The method of claim 13, wherein positioning the one or more vacuum pick pad assembly against the surface of the wafer comprises conformally sealing a wafer contact portion of each of the one or more gimballed pad against the wafer surface.

19. The method of claim 13, wherein positioning the end effector proximate to the wafer comprises detecting the presence of a wafer near the end of the end effector using one or more mapping sensor component coupled to an end of the end effector.

20. The method of claim 13, wherein creating suction at the gimballed pad comprises connecting the gimballed pad to a suction source via a suction path arranged within the pick body.
